(19) United States
(12) Patent Application Publication
(10) Pub. No.: US 2008/0080284 A1
(43) Pub. Date: Apr. 3, 2008

(54) METHOD AND APPARATUS FOR REFRESHING MEMORY CELLS OF A MEMORY

(76) Inventors: Peter Mayer, Neubiberg (DE); Wolfgang Spirkl, Germering (DE); Markus Balb, Munich (DE); Christoph Bilger, Munich (DE); Martin Brox, Munich (DE); Thomas Hein, Munich (DE); Michael Richter, Ottobrunn (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/532,276

(22) Filed: Sep. 15, 2006

(51) Int. Cl. G11C 7/00; G11C 29/00

(52) U.S. Cl. 365/222; 365/201

(57) ABSTRACT

Method and apparatus for refreshing selective memory cells. A refresh circuit is connected with the memory cells and operates to refresh data stored in the memory cells on the basis of the values of valid bits having a predefined association with the memory cells.

### BACKGROUND OF THE INVENTION

Semiconductor devices are used for integrated circuits in a variety of electrical and electronic applications, such as computers, cellular phones, radios and televisions. A particular type of semiconductor device is a semiconductor storage device, such as a random access memory (RAM) device. Random access memory devices include storage cells arranged in a two-dimensional array with two sets of select lines, word lines and bit lines. An individual storage cell is selected by activating its word line and its bit line. RAM devices are considered random access because any memory cell in an array may be accessed directly if the row and column that intersect at that cell are known.

A commonly used form of a RAM is known as a dynamic random access memory (DRAM). A DRAM has memory cells with a select transistor and capacitor. Data information is stored as an electrical charge in the capacitor. The stored charge tends to dissipate over a time due to charge leakage from the capacitor. In order to prevent the charge from being lost, the memory cells of DRAMs have to be regularly read and then have their contents re-written which is referred to as a refresh operation of the memory cells. Each of the memory cells in a DRAM must be periodically refreshed in this manner, wherein the maximum refresh period is determined by a variety of process parameters and is defined by the device manufacturer typically in accordance with predetermined standards.

Conventional DRAM may have on-chip control logic for automatically carrying out an externally or internally generated refresh command. The on-chip refresh logic would make a refresh process transparent to the user by inputting a refresh command from, for example, a memory controller, and internally carrying out all the logical steps necessary to refresh some or all of the memory cells in the allotted time period, including address generation, word line and bit line activation, and returning the chip to a precharge state. Refreshing the memory cells consumes power. A DRAM memory may have several memory banks. A conventional method to reduce a power consumption for refreshing memory cells of a DRAM is to refresh only individual memory banks or parts of the memory banks.

### SUMMARY OF THE INVENTION

An embodiment of the invention refers to a memory with memory cells, with a refresh circuit being connected with the memory cells, wherein the refresh circuit controls refreshing data stored in the memory cells. The memory comprises a storage circuit with valid bits, wherein a valid bit is assigned to at least a subset of the memory cells. The refresh circuit checks the valid bits and refreshes only the memory cells that are assigned to a valid bit in which an enable value is stored.

Another embodiment of the invention refers to a memory with memory cells, with a refresh circuit being connected with the memory cells. The refresh circuit controls refreshing data stored in the memory cells. The memory comprises a storing circuit with valid bits, wherein a valid bit is assigned to at least a subset of the memory cells. The memory comprises an evaluating circuit that checks the valid bits and delivers an enable value if an enable value is stored in the valid bit. The refreshing circuit controls the refreshing of only these memory cells that are assigned to a valid bit in which an enable value is stored. The evaluating circuit writes an enable value in a valid bit that is assigned to a subset of memory cells of the memory if a writing circuit writes data in a memory cell of the subset of the memory.

In a further embodiment the invention refers to a method of refreshing data of memory cells of a memory with a storing circuit with valid bits. The valid bit is assigned to at least a subset of the memory cells. The valid bit is checked and only the memory cells that are assigned to a valid bit with an enable value are refreshed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic drawing of a memory circuit;

FIG. 2 depicts a detail view of the memory cells of the memory;

FIG. 3 depicts a refresh circuit;

FIG. 4 illustrates a block diagram of another embodiment of a refresh circuit.

### DETAILED DESCRIPTION OF THE PREFERRED EMBODIMENT

The present invention generally relates to microelectronic devices. More particularly, the invention relates to programmable structures suitable for various integrated circuit applications, for example, in memory devices.

The present invention may be described in terms of various functional components. It should be appreciated that such functional components may be realized by any number of hardware or structural components configured to perform the specified functions. For example, the present invention may employ various integrated components comprised of various electrically devices, such as resistors, transistors, capacitors, diodes and such components, the behaviour of which may be suitably configured for various intended purposes. In addition, the present invention may be practised in any integrated circuit application where an effective reversible polarity is desired. Such general applications may be appreciated by those skilled in the art in light of the present disclosure are not described in detail. Further, it should be noted that various components may be suitably coupled or connected to other components within exemplary circuits, and that such connections and couplings can be realized by direct connection between components and by connections through other components and devices located in between.

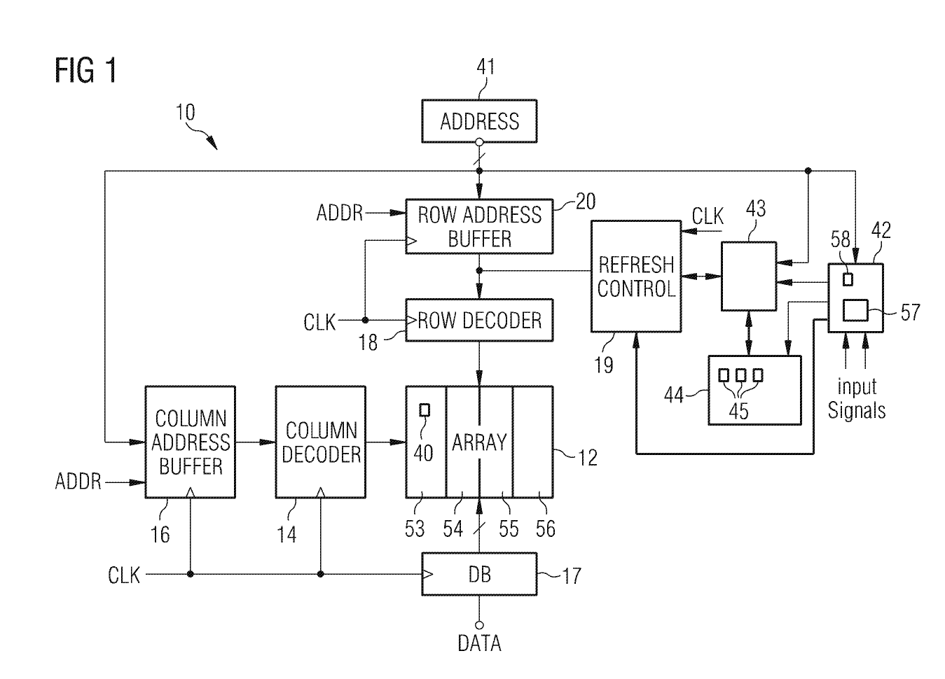

FIG. 1 illustrates a functional block diagram of a DRAM 10 with an array 12 of memory cells 40. The array 12 comprises a plurality of memory cells 40 that are arranged in rows and columns, wherein word lines and bit lines are disposed to access the memory cells 40. At crossing points of a word line and a bit line a memory cell 40 is arranged. To access a particular memory cell in the array 12, an address selection signal ADDR is transmitted to a column address buffer 16 and a row address buffer 20. Furthermore the row address buffer 20 and the column address buffer 16 are connected with an address register 41 that delivers in a time multiplexing mode column addresses and row addresses to the column address buffer 16 and the row address buffer 20. The address selection signal causes the column address buffer 16 to store the addresses that are delivered by the address register 41. The address selection signal also causes the row address buffer 20 to store the row addresses that are delivered by the address register 41. In a typical DRAM, the column address and row address share external pins so that the row address is received at a first time and the columned address is received at a second time. The address selection signal may be transmitted by an external device, such as a memory controller for example.

The column address buffer 16 and the row address buffer 20 are adapted to buffer the address signal. Outputs of the column address buffer 16 are connected to a column decoder 14. Outputs of the row address buffer 20 are connected to a row decoder 18. The column decoder and the row decoder 14, 18 are adapted to decode from the addresses physical positions of the addressed memory cells 40 received from the column address buffer 16 and the row address buffer 20, respectively, to provide signal inputs to the array 12 such that the addressed row and column of the memory cells can be selected. In FIG. 1, the column decoder 14 and the row decoder 18 are shown as single blocks. It should be understood, however, that the decoders may carry out several levels of predecoding and decoding. Some, all, or none of these levels may be clocked. Data that is addressed in the DRAM 10 will be written into the array 12 or read from the array 12 via a data buffer 17. The data buffer 17 and the associated line are provided to represent the read and write path, which may include a large number of lines and other components (in example secondary sense amplifiers).

FIG. 1 also shows a clock input CLK to illustrate that the memory device could be synchronous. To further illustrate this point, the clock signal CLK is provided to each of the blocks. It is understood that while the external clock could be provided to various elements in the array, a number of clocking signals, that may operate continuously or only when needed, may be derived from the clock signal CLK. The DRAM also comprises a refresh circuit 19 that is used to facilitate the refresh of the memory cells in the array 12. The refresh circuit 19 typically contains some form of address generation, often a digital counter. Additionally, the refresh circuit 19 may accept an auto-refresh command input signal from a memory controller 42 or it may internally determine the appropriate time to perform a refresh operation.

The function of an auto-refresh operation is to automatically generate the addresses of the memory cells to be refreshed, and to carry out all the logical steps necessary to perform the refresh operation. It may be advantageous to refresh the memory cells on more than one word line at a time. Furthermore, it may be advantageous to refresh only a subset of the memory cells of the array 12. The array 12 may comprise several memory banks with memory cells. The embodiment of the array 12 shown in FIG. 1 may comprise four memory banks 53, 54, 55, 56. Each of the memory bank 53, 54, 55, 56 may be selectively accessed by the row decoder 18 and the column decoder 14 to read, write or refresh memory cells of the memory banks 53, 54, 55, 56.

In one embodiment, the refresh circuit 19 generates addresses and applies the addresses to the row decoder 18. Certain portions of the refresh circuit 19 may be part of the DRAM. Conversely, some or all of the refresh circuit 19 may reside external to the DRAM 10.

The refresh circuit 19 is connected with an evaluating circuit 43. The evaluating circuit 43 is connected with a storage 44 that comprises at least one valid bit 45. In a further embodiment, several valid bits 45 are arranged in the storage 44. The valid bit 45 is assigned to a subset of memory cells of the array 12. In one embodiment, a valid bit 45 may be assigned to one memory cell 40. In a further embodiment, a valid bit 45 may be assigned to a row of memory cells 40. Either also other subsets of memory elements of the array 12 may be assigned to the valid bit 45. Additionally, the memory controller 42 is connected with the refresh circuit 19 and the evaluating circuit 43. The memory controller 42 is connected with the address register 41. In a further embodiment, the evaluating circuit 43 may be connected with the address register 41.

The refresh circuit 19 delivers the generated addresses of the memory cells that are to be refreshed to the evaluating circuit 43. The evaluating circuit 43 compares a valid bit 45 that is assigned to the memory cells of the received addresses and checks whether the valid bit 45 stores an enable or a disable value. If the valid bit 45 comprises an enable value, then the evaluating circuit 43 delivers an enable signal to the refresh circuit 19. The refresh circuit 19 delivers the generated addresses after receiving an enable signal to the row decoder 18.

If the valid bit 45 comprises a disable value for the received addresses, then the evaluating circuit 43 delivers a disable signal to the refresh circuit 19. The refresh circuit 19 does not deliver an address for which a disable signal is received from the evaluating circuit 43 to the row decoder 18. Thus only the memory cells of the array 12 are refreshed for which a valid bit with an enable value is stored in the storage 44.

The values of the valid bits 45 may be preset at an initializing operation of the DRAM. In a further embodiment, the values of the valid bits 45 may be adjusted during the operation of the DRAM 10.

In one embodiment, the valid bit 45 of a subset of memory cells is set to an enable value if data is written in a memory cell of the subset of memory cells. Therefore, the evaluating circuit 43 may be connected to the address register 41 and may receive an information signal from the memory controller 42 that for the actual addresses of the address register 41 a writing operation is performed. After receiving the writing signal and the addresses, the evaluating circuit 43 searches for the valid bit 45 that is assigned to the received addresses and stores an enable signal to the respective valid bit 45.

In a further embodiment, the evaluating circuit 43 may reset the valid bits 45 to a disable value for a subset of memory cells if for a predetermined time period no reading or writing was processed for the subset of memory cells.

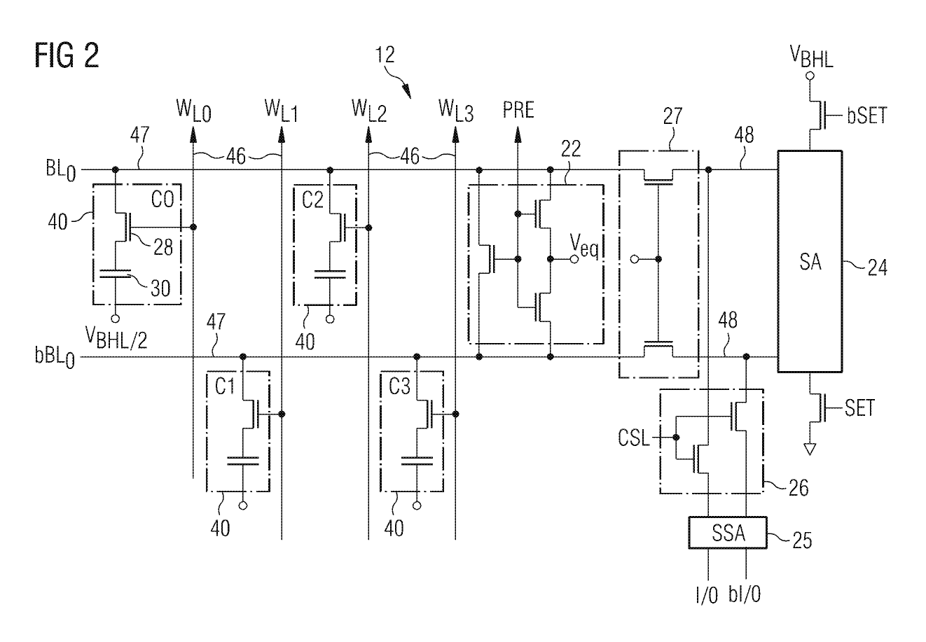

FIG. 2 shows more detail of the memory array 12. The memory array 12 includes a plurality of memory cells 40 arranged in a matrix-type architecture or array. Each memory cell 40 includes an access transistor 28, coupled in series with a capacitor 30. A gate of the access transistor 28 is coupled to a word line 46 and one source/drain region of the transistor 28 is coupled to a bit line 47. A second source/drain region of the transistor 28 is coupled to an end of the storage capacitor 30. The other end of the storage capacitor 30 is coupled to a reference voltage, for example a half of the bit line high voltage. The simplified example of FIG. 2 shows only four memory cells 40. It is readily understood that a practical DRAM 10 may contain a plurality of memory cells arranged in an array of rows and columns.

In a further embodiment, the DRAM 10 includes four 128 MB memory quadrants, each of which corresponds to an individual logical memory bank. For accessing a memory cell, a corresponding word line 46 is put on a high voltage that causes the access transistor 28 of each memory cell coupled to that word line to be conductive. Accordingly, charge will travel either to the bit line from the memory cell (in the case of a physical 1) or from the bit line to the memory cell (in the case of a physical 0). In the depicted detail, two bit lines 47 are connected with a sense amplifier 24. The two bit lines are guided over a passing section 27 comprising two transistors. In this embodiment, the passing section 22 is switching a current state to connect the two bit lines 47 with the sense amplifier 24. The pass section 27 is provided to isolate the sense amplifier 24 from the bit lines 47 if necessary. By using the pass section 27, the sense amplifier 24 may be shared by multiple bit lines. The sense amplifier 24, when activated by signal SET, will sense the physical 1 or 0 and generate a differential voltage that corresponds with the signal read from the memory cell. A precharge circuit 22 includes a plurality transistors (3 shown) and puts the bit lines at Veq when the transistors are conductive (i.e., closed).

A second passing section 26 with two transistors is provided between each column and local data lines 48. Since the sense amplifier 24 associated with each column will generate a bit that corresponds to a memory cell associated with the selected row (as determined by the selected word line), a column select signal CSL is provided to the second pass section 26 to select one of the columns, which is coupled to a local data line 48. Some architectures will include multiple I/Os in which case a single select signal CSL is coupled to the pass sections of more than one column.

A secondary sense amplifier 25 is coupled to the second pass section 26 and to I/0 lines to amplify the voltage level and drive this signal across the DRAM. In a further embodiment, the secondary sense amplifier 25 is connected with write buffers for driving the I/0 lines. When a read command is issued, the second pass section 26 gets activated and the primary sense amplifier 24 is connected to the secondary sense amplifier 25.

A write cycle will be performed in a similar fashion as a read cycle. First, a word line 46 that is connected with the row decoder 18 must have been previously activated, for example, a bank is active. Subsequently, data is placed on the I/O lines and the second transfer section 26 is activated by a CSL signal. During a write cycle, the secondary sense amplifier 25 is not activated, but the write drivers are connected instead by the second passing section 26 with the local data lines 48. The write drivers overwrite the primary sense amplifier, causing the two bit lines to change (only in the case of a different data state) the voltages and the data is transferred to the memory cell 40.

In addition to read and write cycles, the DRAM device must refresh each of its memory cells 40 within a specified time period, or the data may be lost. The requirement to refresh a DRAM 10 is integral to the capacitor structure of the individual memory cells 40 as the stored charge tend to dissipate over time due to charge leakage from the capacitor. Each of the cells must be read and then written back in order to restore, or refresh, the data-bearing charge before the charge dissipates too much to be reliable read. The rate at which this charge dissipation occurs is controlled by various manufacturing in process parameters, therefore, the maximum allowable time between refresh cycles is typically specified by the manufacturer in accordance with defined standards.

The refresh operation may take place when the DRAM is idle, in example, there are no data read or write operations being performed, or when the memory controller determines that the maximum allowable refresh period is about to expire. Below are discussed the exemplary modes of refreshing a DRAM device that can utilize concepts of the present invention. During a self refresh, a single command is issued from the memory controller 42 to the refresh circuit 19 and the refresh circuit 19 refreshes all the memory cells 40 of the array 12 or an individual memory bank 53, 54, 55, 56 in sequence, whereby also a plurality of memory cells can be refreshed simultaneously.

During an auto-refresh, the refresh circuit 19 automatically generates the row addresses and refreshes each row upon receipt of a command from the memory controller 42. Auto-refresh may be executed in two modes: distributed mode or burst mode. In the distributed mode, the refresh circuit 19 will refresh one or more rows in sequence, but not the entire array or memory bank at once. The memory controller 42 keeps track of the time elapsed since the last refresh of each memory cell 40 or memory bank of memory cells, and can thus cycle through the entire array 12 within the maximum refresh period by performing multiple refresh steps. In the burst refresh mode, the memory controller 42 provides a series of refresh commands to the refresh circuit 19 to refresh the entire array 12.

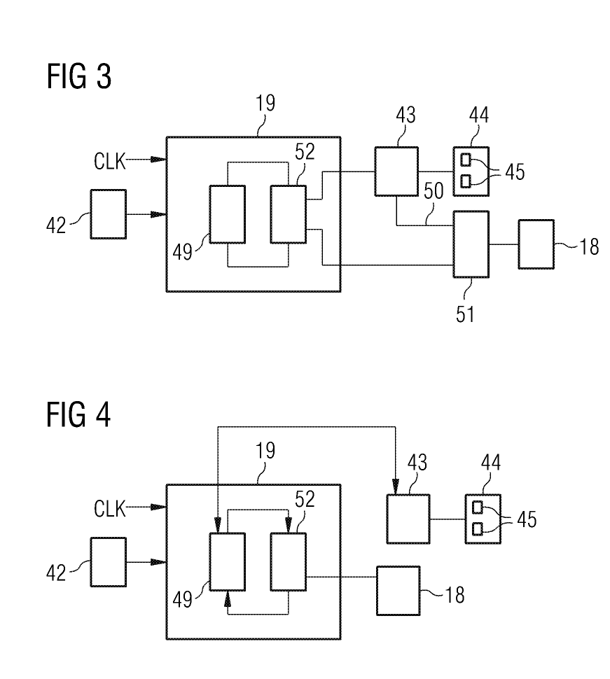

FIG. 3 depicts an embodiment of a refresh circuit 19. The refresh circuit 19 comprises a counter circuit 52 and an incrementing circuit 49. The refresh circuit 19 starts at a starting address, delivers the starting address to the evaluating circuit 43. The evaluating circuit 43 checks a valid bit assigned to the starting address and outputs an enable signal by an enable line 50 to an AND gate 51. The evaluating circuit 43 delivers an enable signal to the AND gate 51 if the valid bit 45 that is assigned to the starting address has an enable value. If the valid bit 45 assigned to the starting address has a disable value, then the evaluating circuit 43 delivers a disable signal on the enable line 50 to the AND gate 51. Additionally, the refresh circuit 19 delivers the starting address to the AND gate 51. The AND gate 51 passes a starting address to the row decoder 18 if the signal on the enable line 50 is an enable signal. If a disable signal is on the enable line 50, then the AND gate 51 does not pass the starting address to the row decoder 18.

The refresh circuit 19 increments the starting address for a predetermined value with the incrementing circuit 49 and delivers the incremented address to the AND gate 51 and the evaluating circuit 43. The evaluating circuit 43 checks the valid bit 45 that is assigned to the incremented address. Depending on the value of the valid bit 45, the evaluating circuit 43 delivers an enable or a disable signal to the AND gate 51. The AND gate 51 passes the incremented address to the row decoder 18 if an enable signal is delivered on the enable line 50.

The refresh circuit 19 increments starting from the starting address to an end address. Depending on the values of the valid bits of the incremented addresses, the AND gate 51 delivers the incremented addresses to the row decoder 18. Therefore, only the memory cells 40 with valid bits 45 with enable values are refreshed. Thus it is possible to refresh subsets of memory cells 40 of the array 12.

Referring to FIG. 1, a method is explained to adjust the value of the valid bits during operating the DRAM 10.

In the embodiment in which the evaluating circuit 43 is connected to the address register 41 and to the memory controller 42, the evaluating circuit 43 receives information for which addresses that means for which memory cells a writing operation is processed. If a writing operation is processed for an address of memory cells, then the evaluating circuit 43 determines the valid bits 44 that correspond to the memory cell address and stores an enable value in the valid bit. Thus the valid bits 45 are programmed to an enable value if a data is written in the respective memory cell. Furthermore, the evaluating circuit 43 may monitor the reading and writing operations and the evaluating circuit 43 may store a disable value in the corresponding valid bits 45 if for a predetermined period of time no writing or reading operation has been performed with the memory cells that are assigned to the valid bit.

FIG. 4 depicts another embodiment of a refresh circuit 19, whereby a counter circuit 52 delivers a starting address to an incrementing circuit 49. The incrementing circuit 49 delivers the starting address to the evaluating circuit 43. The evaluating circuit 43 checks the valid bit 45 assigned to the starting address and delivers an enable value to the incrementing circuit 49 if the valid bit stores an enable value. If the valid bit stores a disable value, the evaluating circuit 43 delivers a disable signal to the incrementing circuit 49. The counter circuit 52 may be a binary counter, and upon a refresh command from the memory controller 42, the counter circuit 52 starts incrementing. If the valid bit stores a disable value, then the incrementing circuit 49 increments the address again and delivers the incremented address to the evaluating circuit 43. If the incrementing circuit 49 receives an enable signal, then the incrementing circuit 49 delivers the address to the counter circuit 52. The counter circuit 52 delivers the received address to the row decoder 18 that processes a refresh operation for this address as discussed above.

The arrangements discussed above allow the refresh command period to be flexible adjusted to the amount of relevant data currently stored in the DRAM 10. Depending on the embodiment, the valid bits may be automatically set upon a write command to the related bank, row and column address. A reset of the valid bits 45 may require a specific action from the memory controller 42. In one embodiment, a write valid control signal is added to the list of command signals that are stored in the memory controller 42. The write valid command will activate the write valid signal. The address lines specify the bank and row address of the memory cells of the valid bits that are to be invalidated. If the write valid command is received from the memory controller 42 by input signals, the memory controller 42 delivers a reset signal to the evaluating circuit 43. The evaluating circuit 43 resets the value bits of the memory cells whose addresses are delivered from the address register 41 to the evaluating circuit 43.

In a further embodiment, a modified write command will be used to access the storage 44 with the valid bits 45. One advantage of this implementation is that no extra signals are required. The procedure is at follows: At first a specific reset valid bit flag in a mode register 57 (FIG. 1) of the memory controller 42 is set by applying a mode register set command to the input of the memory controller. The flag will instruct a command decoder 58 of the memory controller to interpret the next write command as a write valid command. A write command is applied to the input of the memory controller 42. The address of the addresses register specifies a bank and a row of a memory cell whose valid bit is to be invalidated. The memory controller will in one embodiment reset the addressed valid bits in the storage 44. The reset valid bit flag is automatically reset with the write valid command. Alternatively, the reset valid flag will not self reset but require being reset by a mode register set command that will allow bursts of write valid commands to be issued. In a further embodiment, the evaluating circuit 43 receives a reset command from the memory controller 42 and the evaluating circuit 43 resets the respective valid bit 45.

In a third implementation, the whole storage 44 can be reset in a single step. This can be achieved in example by adding a specific reset valid signal to the command list or use a reset valid memory flag in the mode register 57 in combination with a mode register set command. Alternatively, this reset function can be made bank specific by using a bank address. This reset function would be advantageous for example after a power-up memory test, which would leave all valid bits 45 being set due to the memory test, but result in no relevant data being stored in the memory.

In a further embodiment, a destructive read command is added to the memory's command set. The read operation would be executed as a regular read command, but the associated valid bit would be reset if a destructive read command is received from the memory controller 42.

While the foregoing is directed to embodiments of the present invention, other and further embodiments of the invention may be devised without departing from the basic scope thereof, and the scope thereof is determined by the claims that follow.

What is claimed is:

1. A memory, comprising:
a plurality of memory cells;
a storage circuit for storing valid bits, wherein a valid bit is assigned to at least a subset of the memory cells; and
a refresh circuit connected with the memory cells, wherein the refresh circuit refreshes data stored in the memory cells; and wherein the refresh circuit checks the valid bits and refreshes only those memory cells that are assigned a valid bit set to an enable value.

2. The memory of claim 1, wherein the memory cells are arranged in rows and columns, and wherein each valid bit is assigned to a respective row of memory cells.

3. The memory of claim 1, wherein the valid bits are specific to addresses of the memory cells, wherein the refresh circuit generates an address of a memory cell that is to be refreshed, wherein the refresh circuit is connected with an evaluating circuit, wherein the refresh circuit delivers the address to the evaluating circuit, wherein the evaluating circuit is connected to the storage circuit and checks the value of the valid bits that are assigned to the received address and sends an enable signal to the refresh circuit if the checked valid bit is set to an enable value, wherein the refresh circuit refreshes only the memory cell at an address for which an enable signal is received from the evaluating circuit.

4. The memory of claim 3, wherein the refresh circuit comprises a counter circuit, wherein the refresh circuit is connected with an input of an AND gate and an input of the evaluating circuit, wherein a second input of the AND gate is connected with an output of the evaluating circuit that delivers an enable signal if the address delivered from the refresh circuit refers to a valid bit with an enable value, wherein the counter increments an address starting with a starting address and outputs the incremented address to the AND gate and to the evaluating circuit, wherein the AND gate delivers an address to a decoder for refreshing the memory cell belonging to the received address if the AND gate receives the enable signal from the evaluating circuit.

5. The memory of claim 3, wherein the refresh circuit comprises a counter circuit, wherein the counter circuit is connected with an output of the evaluating circuit, wherein the counter output is connected with an input of the evaluating circuit, wherein the counter increments an address from a starting address to an end address and delivers the incremented address to the evaluating circuit, wherein the evaluating circuit checks a valid bit that is assigned to the delivered address and delivers an enable signal to the counter circuit if an enable value is stored in the checked valid bit, wherein the counter delivers the address to a decoder for refreshing the respective memory cell if the enable signal is received from the evaluating circuit referring to the address.

6. The memory of claim 3, further comprising a writing circuit, wherein the evaluating circuit writes an enable value in a valid bit if the writing circuit writes data in a memory cell of the subset of the memory.

7. The memory of claim 1, further comprising a writing circuit and a reset input, wherein the evaluating circuit writes an enable value in a valid bit if the writing circuit writes data in a memory cell of the subset of memory cells, wherein a reset signal on the reset input causes the evaluating circuit to write a disable value in the valid bits of the memory cells in which data are written.

8. The memory of claim 1, further comprising:
a mode register with a write bit; and
a writing circuit; wherein the writing circuit writes data in the memory cells, wherein the evaluating circuit writes a disable value in the valid bit if data is written in the memory cells of the subset assigned to the valid bit and if a disable value is stored in the write bit of the mode register.

9. The memory of claim 8, further comprising a control command circuit connected with the mode register, wherein the control command circuit changes the value of the write bit of the mode register on receipt of a set command on the input.

10. The memory of claim 1, further comprising:
a writing circuit;
a memory controller, wherein the memory controller writes an enable data in the valid bit if the writing circuit writes data in a memory cell of the subset that the valid bit is assigned to; and
a mode register with reset bits assigned to subsets of the memory cells, wherein the mode register is connected with the memory controller, wherein the memory controller writes a disable value to the valid bit if a disable value is stored in the reset bit.

11. A memory, comprising:
a plurality of memory cells;
a refresh circuit connected with the memory cells, wherein the refresh circuit controls refreshing data stored in the memory cells;
a storing circuit with valid bits, wherein each valid bit is assigned to at least a respective subset of the memory cells; and
an evaluating circuit that checks the valid bits and outputs an enable value signal to the refreshing circuit if an enable value is stored in the checked valid bit, wherein the evaluating circuit writes an enable value in a valid bit that is assigned to a respective subset of memory cells if a writing circuit writes data in a memory cell of the subset of the memory; wherein the refreshing circuit, responsive to the enable value signal, controls the refreshing of only those memory cells that are assigned to a valid bit in which a respective enable value is stored.

12. The memory of claim 11, further comprising a memory controller with a reset mode, wherein a receipt of a reset signal causes the memory controller to write a disable value in the valid bits of the memory cells whose addresses are delivered by the refresh circuit to the memory controller.

13. The memory of claim 11, further comprising:
a mode register with a write bit; and
a memory controller configured to write a disable value in the valid bit if the writing circuit writes data in the memory elements of the subset assigned to the valid bit and if a disable value is stored in the write bit of the mode register.

14. The memory of claim 13, further comprising a control command circuit connected with the mode register, wherein the control command circuit changes the value of the write bit of the mode register on receive of a set command on an input.

15. The memory of claim 11, further comprising:
a mode register with reset bits assigned to subsets of the memory cells; and
a memory controller connected to the mode register, wherein the memory controller writes a disable value to the valid bit if a disable value is stored in the reset bit.

16. A method of refreshing data stored in memory cells of a memory, comprising:
providing a storing circuit with valid bits, wherein a valid bit is assigned to at least a subset of the memory cells;
checking a value of a valid bit stored in the storing circuit; and
refreshing only those memory cells assigned to the valid bit if the checked value of the valid bit is set to an enable value.

17. The method of claim 16, wherein the memory cells are arranged in rows and columns, wherein the checked valid bit is assigned to a row of memory cells.

18. The method of claim 16, wherein the checked valid bit is associated with a particular address of the refreshed memory cells, wherein the particular address is generated by a refresh circuit that performs the refreshing.

19. The method of claim 16, wherein the valid bit whose value is checked is determined by first incrementing an address to generate an incremented address corresponding to the valid bit.

20. The method of claim 16, further comprising:
writing the enable value to the valid bit if data is written in a memory cell of the subset of the memory cells.

21. The method of claim 16, wherein a disable value is written in the valid bit if a reset mode is set.

22. The method of claim 16, further comprising:
if data is written to the subset of the memory cells and if a disable value is stored in a write bit of a mode register, writing a disable value in the valid bit.

23. The method of claim 16, further comprising:
writing an enable value in the valid bit if data is written in a memory cell of the subset of memory cells; and
writing a disable value in the valid bit if a disable value is stored in a reset bit assigned to the subset of the memory cells, wherein the reset bit is stored in a mode register.
